(19) United States
(12) Patent Application Publication
(10) Pub. No.: US 2014/0030876 A1
(43) Pub. Date: Jan. 30, 2014

(54) METHODS FOR FABRICATING HIGH CARRIER MOBILITY FINFET STRUCTURES

(71) Applicants: Stefan Flachowsky, Dresden (DE); Ralf Illgen, Dresden (DE)

(72) Inventors: Stefan Flachowsky, Dresden (DE); Ralf Illgen, Dresden (DE)

(73) Assignee: GLOBALFOUNDRIES Inc., Grand Cayman (KY)

(21) Appl. No.: 13/560,372

(22) Filed: Jul. 27, 2012

(51) Int. Cl. H01L 21/84; H01L 21/263

(52) U.S. Cl. 438/479; 438/701; 257/E21.7; 257/E21.333

(57) ABSTRACT

A method for fabricating an integrated circuit having a FinFET structure includes providing a semiconductor substrate comprising silicon and a high carrier mobility material, forming one or more fin structures on the semiconductor substrate, and subjecting the substrate to a condensation process for the condensation of the high carrier mobility material. The condensation process results in the formation of condensed fin structures formed substantially entirely of the high carrier mobility material and a layer of silicon oxide formed over the condensed fin structures. The method further includes removing the silicon oxide formed over the condensed fin structures so as to expose the condensed fin structures.

### TECHNICAL FIELD

The present disclosure generally relates to semiconductor devices and methods for fabricating semiconductor devices, and more particularly the present disclosure relates to FinFET structures and methods for fabricating the FinFET structures.

### BACKGROUND

In contrast to traditional planar metal-oxide-semiconductor field-effect transistors (MOS transistors or MOSFETs), which are fabricated using conventional lithographic fabrication methods, nonplanar MOSFETs incorporate various vertical transistor structures. One such semiconductor structure is the “FinFET,” which takes its name from the multiple thin silicon “fins” that are used to form the respective gate channels, and which are typically on the order of tens of nanometers in width.

The prior art is replete with different techniques and processes for fabricating MOS transistor semiconductor devices, including both planar and non-planar devices. In accordance with typical fabrication techniques, a MOS transistor integrated circuit is formed by creating a device structure on a semiconductor substrate, where the device structure includes a gate stack formed on a layer of semiconductor material, and source and drain regions formed in the semiconductor material to define a channel region under the gate stack.

In recent years, a principal focus for improved MOS transistor performance has been increasing the mobility and drive current in the transistor. The demand for ever increasing performance and switching speed of integrated circuits requires continuously higher carrier mobility and drive currents. One approach to this problem is to introduce continuously higher channel stresses in order to achieve higher carrier mobility and drive currents. However, many stressors lose their effectiveness for three-dimensional device architectures, such as FinFET architectures. Another approach involves the use of a channel material with intrinsically higher carrier mobility than silicon including, for example, the various group III-V semiconductor alloys such as InP or GaAs, or group IV semiconductor materials such as Ge. However, numerous problems arise with using these “new” channel materials, particularly with the substrates used to form them. For example, non-silicon substrates, such as Ge substrates, are considerably more expensive than silicon substrates, and as such are not suitable for large-scale fabrication operations. Furthermore, the occurrence of defects in non-silicon substrates is orders of magnitude greater than in silicon substrates. Still further, non-silicon substrates are not even available in 300 mm state-of-the-art wafer sizes, and as such would be difficult to integrate into an existing silicon-compatible fabrication flow.

Accordingly, it is desirable to provide FinFET structures and methods for fabricating FinFET structures with improved carrier mobility and drive current. It is further desirable to provide methods for fabricating such FinFET structures that do not have significant fabrication cost increases over those currently employed in the art. Furthermore, other desirable features and characteristics of the present invention will become apparent from the subsequent detailed description of the invention and the appended claims, taken in conjunction with the accompanying drawings, the brief summary, and this background of the invention.

### BRIEF SUMMARY

Methods for fabricating FinFET structures are provided herein. In accordance with an exemplary embodiment, a method for fabricating an integrated circuit having a FinFET structure includes providing a semiconductor substrate comprising silicon and a high carrier mobility material, forming one or more fin structures on the semiconductor substrate, and subjecting the substrate to a condensation process for the condensation of the high carrier mobility material. The condensation process results in the formation of condensed fin structures formed substantially entirely of the high carrier mobility material and a layer of silicon oxide formed over the condensed fin structures. The method further includes removing the silicon oxide formed over the condensed fin structures so as to expose the condensed fin structures.

In accordance with another exemplary embodiment, a method for fabricating an integrated circuit having a FinFET structure includes providing a SiGe-on-insulator substrate, etching one or more fin structures in a SiGe layer of the SiGe-on-insulator substrate, and subjecting the substrate to a condensation process for the condensation of Ge. The condensation process results in the formation of condensed fin structures formed substantially entirely of the Ge and a layer of silicon oxide formed over the condensed fin structures. The method further includes etching the silicon oxide formed over the condensed fin structures so as to expose the condensed fin structures.

In accordance with yet another exemplary embodiment, a method for fabricating an integrated circuit having a FinFET structure includes providing a SiGe-on-insulator substrate, anisotropically etching one or more fin structures in a SiGe layer of the SiGe-on-insulator substrate, the one or more fin structure being from about 40 nm to about 60 nm in width, and subjecting the substrate to a condensation process for the condensation of Ge. The condensation process results in the formation of condensed fin structures formed substantially entirely of the Ge and a layer of silicon oxide formed over the condensed fin structures. Subjecting the substrate to a condensation process includes subjecting the substrate to an atmosphere including substantially 100% oxygen, subjecting the substrate to a temperature from about 1000° C. to about 1200° C., and subjecting the substrate for a time period from about 10 minutes to about 30 minutes. The method further includes anisotropically wet etching the silicon oxide formed over the condensed fin structures so as to expose the condensed fin structures.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

Various aspects of the disclosure will be more readily understood from the following detailed description taken in conjunction with the accompanying drawings that depict different embodiments of the disclosure, in which:

FIGS. 1-5 are cross-sectional views of a SiGe-on-insulator substrate illustrating methods for fabricating a FinFET structure with improved carrier mobility and drive current in accordance with embodiments of the present disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

For the sake of brevity, conventional techniques related to semiconductor device fabrication may not be described in detail herein. Moreover, the various tasks and process steps described herein may be incorporated into a more comprehensive procedure or process having additional steps or functionality not described in detail herein. In particular, various steps in the manufacture of semiconductor based integrated circuits are well known and so, in the interest of brevity, many conventional steps will only be mentioned briefly herein or will be omitted entirely without providing the well-known process details.

Techniques and technologies described herein may be utilized to fabricate MOS transistor devices, including NMOS transistor devices, PMOS transistor devices, and NMOS/PMOS device combinations referred to as CMOS devices. Although the term “MOS device” properly refers to a device having a metal gate electrode and an oxide gate insulator, that term will be used throughout to refer to any semiconductor device that includes a conductive gate electrode (whether metal or other conductive material) that is positioned over or around a gate insulator (whether oxide or other insulator) which, in turn, is positioned over a semiconductor region or regions, or around the same as in the case of the FinFET devices described herein. As used herein, the term “FinFET” refers both to finned devices where only the vertical walls of the fins are influenced by gate voltages (also known as “double gate” or “dual-gate” devices) and to finned devices where the fin top surface as well as the fin vertical walls are influenced by gate voltages (also known as “tri-gate” or “triple gate” devices).

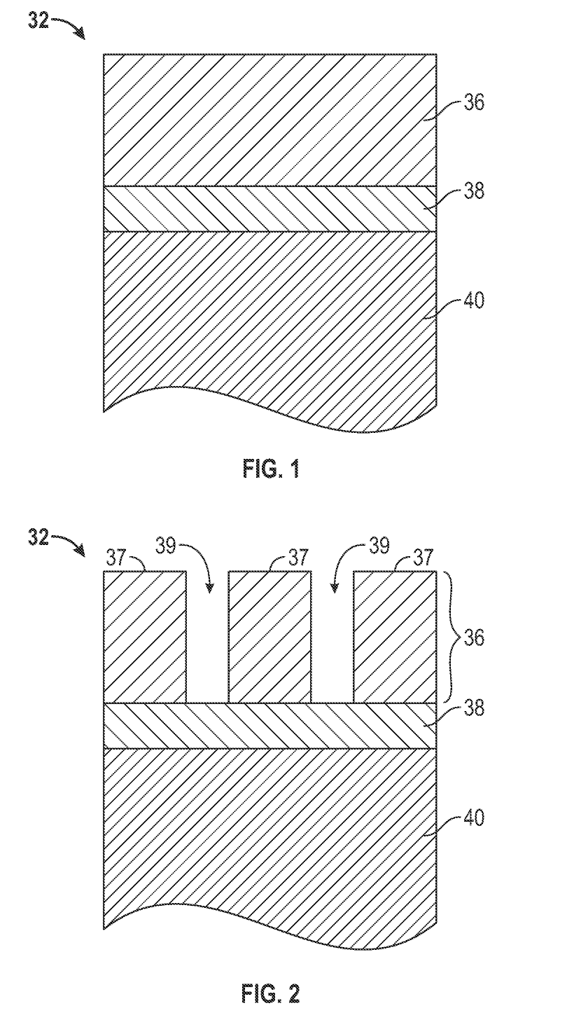

As illustrated in cross section in FIG. 1, the manufacture of a FinFET structure in accordance with an embodiment of the present disclosure begins with providing a silicon germanium (SiGe) substrate 32. Preferably the silicon germanium (SiGe) substrate includes silicon and between about 10 and 30 atomic percent germanium. As used herein, the terms “semiconductor substrate” or more specifically “silicon germanium substrate” will be used to encompass the relatively pure or lightly impurity doped substantially silicon germanium materials typically used in the semiconductor industry. The two terms, “semiconductor substrate” and “silicon germanium substrate” will be used interchangeably herein.

Semiconductor substrate 32 can be a bulk semiconductor substrate, but preferably is a thin layer of silicon germanium material 36 (typically provided between about 50 nm and about 100 nm in thickness) on an insulating layer 38 (typically provided between about 100 nm and about 150 nm in thickness), such as silicon oxide, which, in turn, is supported by a support silicon wafer 40. Such a substrate is commonly referred to as a semiconductor on insulator (SOI) or silicon germanium on insulator (SGOI) substrate. Without loss of generality, but for convenience of description, substrate 32 will hereinafter be referred to as a silicon germanium on insulator or SGOI substrate or simply as a semiconductor substrate.

In other embodiments, the substrate 32 may include silicon and another high carrier mobility material, such as, for example, the various group III-V semiconductor alloys such as InP or GaAs, or group IV semiconductor materials. As with silicon germanium, the alternative substrates are preferably provided with the silicon/high carrier mobility material as a thin layer on an insulating layer, the insulating layer being supported by a silicon wafer. For simplicity of description, the present disclosure will hereinafter be described with respect to the example of a SGOI substrate, but it will be appreciated that other substrates including high carrier mobility materials may likewise be employed.

With reference now to FIG. 2, the manufacture of the FinFET structure proceeds with a patterning and etching step applied to the SiGe layer 36 to form one or more lines or “fins” 37 of SiGe material overlying the insulator layer 38. Three such fins 37 are illustrated in FIG. 2. In order to achieve fins 37 with uniform thickness etched all the way to the insulator layer 38, as shown in FIG. 2, it is desirable to employ anisotropic etching techniques such as, for example, reactive ion etching (RIE). In accordance with one embodiment, patterning and etching are performed so as to provide fin widths that are each between about 40 nm and about 60 nm. However, the final dimensions and aspect ratio of the completed fin structures of the FinFET device, as will be discussed in greater detail below, will be smaller than the fins 37 formed by initially etching the SiGe layer 36. As such, the width of the etched fins 37 should be larger than the width of the fins desired in the completed FinFET structure. Furthermore, an etched space 39 between each fin 37 can typically range between about 5 nm and about 20 nm, but is ultimately dependent on the space desired between each fin structure for the complete IC.

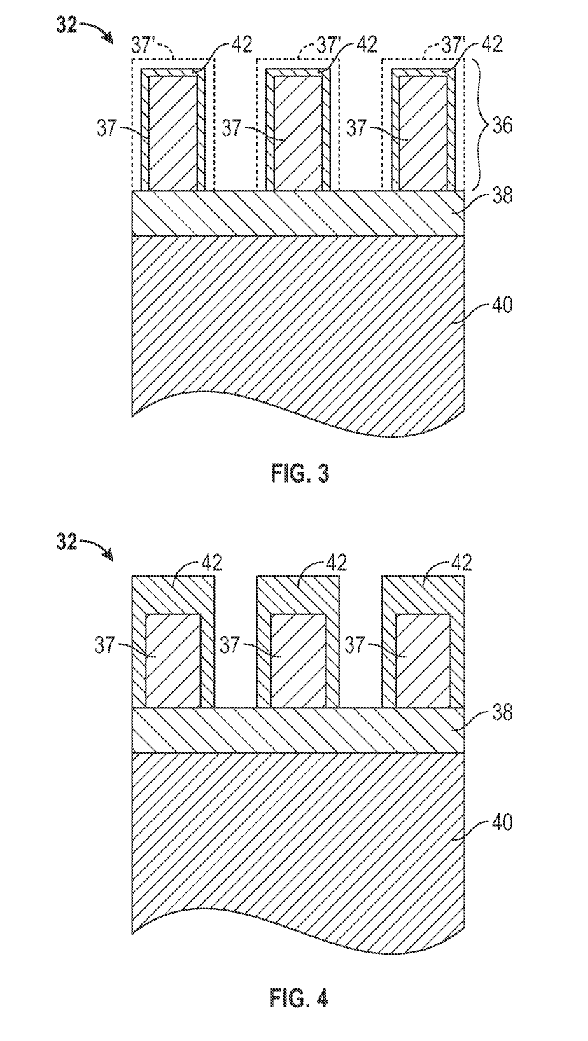

With reference now to FIG. 3, a germanium condensation process is performed. Typical atmospheric and temperature process conditions for germanium condensation include a 100% (or as near thereto as possible) O₂ atmosphere and 1000-1200° C. temperature, respectively. Depending on the thickness of the fins 37, full condensation of germanium in the aforementioned process conditions typically will require a time period of about 10 minutes to about 30 minutes. The time and temperature requirements are further dependent on the original germanium content in the SiGe layer.

As shown in FIG. 3, germanium condensation results in a consumption (i.e., outward diffusion) of the silicon atoms in the SiGe while the germanium atoms remain in place (i.e., in the fins 37), resulting in a steadily increasing germanium content in the fins 37 with increasing process time. The silicon atoms are consumed by reaction with the atmospheric O₂, thereby forming a silicon oxide layer 42 surrounding the SiGe (with an increasing proportion of Ge during the course of condensation) fin structures 37. FIG. 3 illustrates the vertical and lateral dimensions of the SiGe fins 37 being reduced as the germanium condensation process proceeds in time. An outline 37′ of the initial SiGe fins 37 is provided as a frame of reference to illustrate the reduction in dimension. Diffusion of silicon proceeds through the fins 37 from the center of the fins 37 to the periphery of the fins 37, and as such a concentration gradient develops in the fins 37 during the germanium condensation process wherein the center of the 37 has a greater concentration of silicon than the periphery of the fins 37.

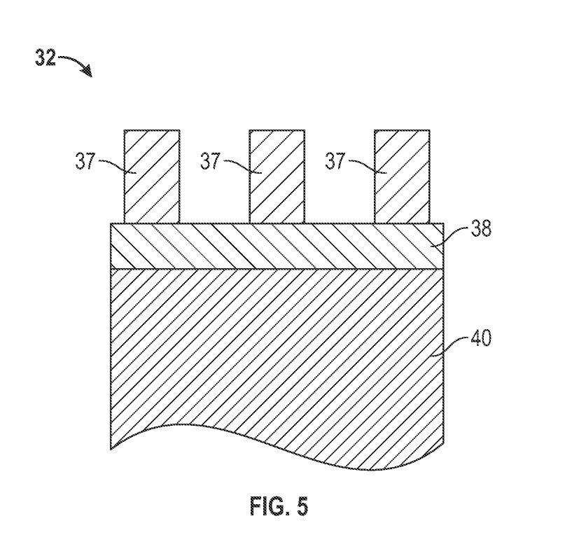

With reference now to FIG. 4, after the fins 37 have been subjected to the germanium condensation process condition for a sufficient period of time (i.e., about 10 minutes to about 30 minutes as noted above), the germanium condensation has proceeded to completion such that substantially pure germanium fins 37 remain encapsulated within the silicon oxide layer 42. At this point the silicon consumption/oxidation process ceases and no further dimension change occurs.

Thereafter, a wet etch process that is selective to germanium may be employed to remove the silicon oxide layer 42 from around the fins 37, which are now substantially completely germanium, for example at least 95% germanium. Wet etch techniques are known in the art, and include, for example, the use of dilute hydrogen fluoride. Preferably, the wet etch process employed is isotropic, to allow for etching of the silicon oxide along the side of the fins 37 without any damage to the shape of the fins 37. After etching, the resulting structure is illustrated in FIG. 5, and includes a plurality of substantially pure germanium fins 37 disposed over an insulating layer 38.

It will be appreciated that germanium has the highest hole mobility among all semiconductors and semiconductor alloys and is therefore, in one embodiment, preferable for use as a channel material in pFETs. Furthermore, the electron mobility in germanium is up to two times higher than silicon, making germanium also suitable for use as nFETs, in another embodiment. Thus, the structure disclosed in FIG. 5 can be used to fabricate a plurality of FinFET structures of both the p- and n-types. Of course, as noted above, other high-carrier mobility materials may similarly be employed in the methods described herein. It is expected that the condensation process conditions for numerous such alternative materials will be readily discoverable by those having ordinary skill in the art with reference to the teachings herein.

Thereafter, further processing steps can be performed to fabricate the integrated circuit, as are well-known in the art. For example, further steps (not shown) conventionally include, for example, the formation of a gate structure overlying the fins 37, the formation of contacts, and the formation of one or more patterned conductive layer across the device with dielectric layers thereinbetween, among many others. The subject matter disclosed herein is not intended to exclude any subsequent processing steps to form and test the completed integrated circuit as are known in the art.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

1.-12. (canceled)

13. A method for fabricating an integrated circuit having a FinFET structure, comprising:
providing a SiGe-on-insulator substrate;
etching one or more fin structures in an SiGe layer of the SiGe-on-insulator substrate;
subjecting the substrate to a condensation process for the condensation of Ge, wherein the condensation process results in the formation of condensed fin structures comprised substantially entirely of the Ge and a layer of silicon oxide formed over the condensed fin structures, wherein subjecting the substrate to a condensation process comprises subjecting the substrate to a temperature from about 1000° C. to about 1200° C.; and
etching the silicon oxide formed over the condensed fin structures so as to expose the condensed fin structures.

14. The method of claim 13, wherein subjecting the substrate to a condensation process comprises subjecting the substrate to an atmosphere comprising substantially 100% oxygen.

15. (canceled)

16. The method of claim 15, wherein subjecting the substrate to a condensation process comprises subjecting the substrate for a time period from about 10 minutes to about 30 minutes.

17. The method of claim 13, wherein etching one or more fin structures comprises anisotropic etching to an insulator layer of the SiGe-on-insulator substrate.

18. The method of claim 13, wherein etching the silicon oxide comprises isotropic wet etching.

19. The method of claim 13, wherein etching one or more fin structures in an SiGe layer of the SiGe-on-insulator substrate comprises etching one or more fin structures having a width from about 40 nm to about 60 nm.

20. A method for fabricating an integrated circuit having a FinFET structure, comprising:
providing a SiGe-on-insulator substrate;
anisotropically etching one or more fin structures in an SiGe layer of the SiGe-on-insulator substrate, the one or more fin structure being from about 40 nm to about 60 nm in width;
subjecting the substrate to a condensation process for the condensation of Ge, wherein the condensation process results in the formation of condensed fin structures comprised substantially entirely of the Ge and a layer of silicon oxide formed over the condensed fin structures, wherein subjecting the substrate to a condensation process comprises subjecting the substrate to an atmosphere comprising substantially 100% oxygen, subjecting the substrate to a temperature from about 1000° C. to about 1200° C., and subjecting the substrate for a time period from about 10 minutes to about 30 minutes; and
isotropically wet etching the silicon oxide formed over the condensed fin structures so as to expose the condensed fin structures.
